(19) United States
(12) Patent Application Publication
(10) Pub. No.: US 2024/0407237 A1
(43) Pub. Date: Dec. 5, 2024

(54) DISPLAY SUBSTRATE, DISPLAY DEVICE, AND MANUFACTURING METHOD FOR DISPLAY SUBSTRATE

(71) Applicant: BOE Technology Group Co., Ltd., Beijing (CN)

(72) Inventors: Qian Wu, Beijing (CN); Weiting Peng, Beijing (CN); Yutong Yan, Beijing (CN); Fang Cheng, Beijing (CN)

(73) Assignee: BOE Technology Group Co., Ltd., Beijing (CN)

(21) Appl. No.: 18/694,066

(22) PCT Filed: Jul. 31, 2023
(86) PCT No.: PCT/CN2023/110365

§ 371 Date: Mar. 21, 2024

(30) Foreign Application Priority Data
Aug. 31, 2022 (CN) 202211054832.2

(51) Int. Cl. H10K 59/80; H10K 59/122; H10K 59/35; H10K 59/38

(52) U.S. Cl. CPC H10K 59/879; H10K 59/122; H10K 59/35; H10K 59/38; H10K 59/873

(57) ABSTRACT

A display base board, a display device and a manufacturing method of the display base board are provided. The display base board includes: a substrate (10); a light emitting layer (20), wherein the light emitting layer (20) includes a plurality of sub-pixels (201); a packaging layer (30); and at least one lens layer (40), wherein each of the at least one lens layer (40) includes a plurality of lens units (401), and the plurality of lens units (401) correspond to the sub-pixels (201) one to one.

### CROSS REFERENCE TO RELEVANT APPLICATIONS

The present disclosure claims the priority of the Chinese patent application filed on Aug. 31, 2022 before the Chinese Patent Office with the application number of 202211054832.2 and the title of “DISPLAY SUBSTRATE, DISPLAY DEVICE, AND MANUFACTURING METHOD FOR DISPLAY SUBSTRATE”, which is incorporated herein in its entirety by reference.

### TECHNICAL FIELD

The present disclosure relates to the technical field of displaying and, more particularly, to a display base board, a display device and a manufacturing method of the display base board.

### BACKGROUND

Organic light emitting diode (OLED) micro-display, which is also referred to as silicon-based OLED display, is a newly developed branch of the industry of displaying. The silicon-based OLED micro-display is mainly consisted of the integrated circuit (IC) manufacturing technique and the OLED technique. The silicon-based OLED micro-display is different from the traditional mobile phones, IPADs, computers and television screens, and usually refers to the display smaller than 2.5 inches. Because the silicon-based OLED displays employ the monocrystalline-silicon wafer as the active driving back panel, the excellent characteristics such as a high PPI (Pixels Per Inch), a high integration level, a small volume, easy carrying, a good shock resistance and an ultra-low power consumption can be more easily realized.

### SUMMARY

According to the first aspect of the present disclosure, a display base board is provided, wherein the display base board includes:

a substrate;

a light emitting layer disposed at one side of the substrate, wherein the light emitting layer includes a plurality of sub-pixels, and at least one of the plurality of sub-pixels includes a plurality of light emitting regions;

a packaging layer disposed at one side of the light emitting layer away from the substrate; and

at least one lens layer disposed on a surface of one side of the packaging layer away from the light emitting layer, wherein each of the at least one lens layer includes a plurality of lens units, and the plurality of lens units correspond to the plurality of sub-pixels one to one; and

each of the plurality of lens units includes one or more lenses, the one or more lenses correspond to the plurality of light emitting regions one to one, and the one or more lenses are configured for causing light rays emitted by the light emitting layer to deflect toward a direction close to a normal of the substrate.

Optionally, a ratio of a distance between a surface of one side of the light emitting layer facing the packaging layer and a surface of one side of each of the at least one lens layer facing the packaging layer to an equivalent focal length of the lens unit is greater than or equal to 0.5, and less than or equal to 1.

Optionally, the distance between the surface of the side of the light emitting layer facing the packaging layer and the surface of the side of each of the at least one lens layer facing the packaging layer is greater than or equal to 0.8 μm, and less than or equal to 1.2 μm.

Optionally, a refractive index of each of the at least one lens layer is greater than or equal to 1.8.

Optionally, a refractive index of the packaging layer and a refractive index of each of the at least one lens layer are equal.

Optionally, the at least one lens layer includes a first lens layer and a second lens layer; and

a material of the first lens layer and a material of the second lens layer are the same or different.

Optionally, the display base plate further includes:

a pixel definition layer disposed between the substrate and the light emitting layer, wherein the pixel definition layer segments each of the plurality of sub-pixels into the plurality of light emitting regions.

Optionally, the display base plate further includes:

a first electrode layer disposed between the pixel definition layer and the substrate, wherein the first electrode layer includes a plurality of first electrodes, and the plurality of light emitting regions located in a same sub-pixel are connected to a same first electrode.

Optionally, the plurality of sub-pixels includes a first sub-pixel, a second sub-pixel and a third sub-pixel; and

quantities of the lenses included by the lens units that at least two of the first sub-pixel, the second sub-pixel and the third sub-pixel correspond to are unequal to each other.

Optionally, the plurality of sub-pixels include a red sub-pixel, a green sub-pixel and a blue sub-pixel; and

a quantity of the lenses included by the lens unit corresponding to the green sub-pixel is greater than a quantity of the lenses included by the lens unit corresponding to the red sub-pixel and a quantity of the lenses included by the lens unit corresponding to the blue sub-pixel; or

the quantity of the lenses included by the lens unit corresponding to the red sub-pixel is greater than the quantity of the lenses included by the lens unit corresponding to the green sub-pixel and the quantity of the lenses included by the lens unit corresponding to the blue sub-pixel.

Optionally, the plurality of sub-pixels include a red sub-pixel, a green sub-pixel and a blue sub-pixel, and a ratio of quantities of the lenses included by the lens units corresponding to the red sub-pixel, the green sub-pixel and the blue sub-pixel is 1:2:1.

Optionally, the plurality of sub-pixels include a red sub-pixel, a green sub-pixel and a blue sub-pixel, and a ratio of quantities of the lenses included by the lens units corresponding to the red sub-pixel, the green sub-pixel and the blue sub-pixel is 3:2:2.

Optionally, the display base plate further includes:

an optical-filter layer disposed at one side of the at least one lens layer away from the packaging layer, wherein optical filters of the optical-filter layer correspond to the sub-pixels one to one;

wherein the optical-filter layer includes a red optical filter, a green optical filter and a blue optical filter.

According to the second aspect of the present disclosure, a display device is provided, wherein the display device includes the display base board according to the first aspect of the present disclosure.

According to the third aspect of the present disclosure, a manufacturing method of a display base board is provided, wherein the manufacturing method includes:

providing a substrate;

forming a light emitting layer at one side of the substrate, wherein the light emitting layer includes a plurality of sub-pixels;

forming a packaging layer at one side of the light emitting layer away from the substrate; and

forming at least one lens layer on a surface of one side of the packaging layer away from the light emitting layer, wherein each of the at least one lens layer includes a plurality of lens units, and the plurality of lens units correspond to the plurality of sub-pixels one to one; and

each of the plurality of lens units includes one or more lenses, and the one or more lenses are for causing light rays emitted by the light emitting layer to deflect toward a direction close to a normal of the substrate.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work.

FIG. 1 shows a schematic structural diagram of a display base board according to an embodiment of the present disclosure;

FIG. 2 shows a schematic structural diagram of a display base board including a first lens layer and a second lens layer according to an embodiment of the present disclosure;

FIG. 3 shows a schematic structural diagram of a display base board having lens units of two lenses according to an embodiment of the present disclosure;

FIG. 4 shows a schematic planar structural diagram of a sub-pixel having one lens according to an embodiment of the present disclosure;

FIG. 5 shows a schematic planar structural diagram of a sub-pixel having two lenses according to an embodiment of the present disclosure;

FIG. 6 shows a schematic planar structural diagram of a sub-pixel having three lenses according to an embodiment of the present disclosure;

FIG. 7 shows a schematic structural diagram of a single sub-pixel including a pixel definition layer according to an embodiment of the present disclosure;

FIG. 8 shows a schematic structural diagram in which a quantity of the lenses included by the lens unit corresponding to the green sub-pixel is greater than quantities of the lenses included by the lens units corresponding to the red sub-pixel and the blue sub-pixel according to an embodiment of the present disclosure;

FIG. 9 shows a schematic structural diagram in which a quantity of the lenses included by the lens unit corresponding to the red sub-pixel is greater than quantities of the lenses included by the lens units corresponding to the green sub-pixel and the blue sub-pixel according to an embodiment of the present disclosure;

FIG. 10 shows a schematic structural diagram of a display base board including an optical-filter layer according to an embodiment of the present disclosure; and

FIG. 11 shows a flow chart of the steps of a manufacturing method of a display base board according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the related art, the pixel densities (Pixels Per Inch, PPI) of silicon-based OLEDs are usually 3000-5000, and the sub-pixels are approximately 5 micrometers. Due to the extra-high resolution, high requirements are raised on the precise processing of the silicon-based OLEDs.

The silicon-based OLEDs are the next-generation display screen of the optical modules of the Virtual Reality (VR) technique and the Augmented Reality (AR) technique, and their product characteristics are also required to satisfy the application scenes of VR/AR. In the VR/AR applications, a higher screen brightness are always an important development goal of the silicon-based OLEDs. Especially, in the application field of VR, in order to pursue low weight and thickness, folded optical path is considered as an important development direction of the forms of VR. However, as restricted by the principle, the upper limit of the light-energy utilization ratio of folded optical path is merely 1/8, and accordingly it is required that the screen has a higher brightness.

The solution of micro-lens is a commonly used method for brightness increasing in the silicon-based OLEDs. Micro-lenses of the equal size to that of the sub-pixels are placed directly over the light emitting layer, and correspond to the sub-pixels one to one. The micro-lenses can perform weak converging to the lights emitted by the light emitting layer at large angles, to point to the normal angle, thereby the brightness at the normal angle is increased. However, in the related art, the micro-lenses are placed at a relatively high height, and therefore the light rays emitted by each of the sub-pixels cannot completely enter the corresponding micro-lens, which causes that the effect of the increasing of the brightness of the display base board is not satisfying.

In view of this, a display base board, a display device and a manufacturing method of a display base board are provided by the present disclosure, in which a substrate, a light emitting layer, a packaging layer and at least one lens layer are provided, wherein the light emitting layer includes a plurality of sub-pixels, at least one of the plurality of sub-pixels includes a plurality of light emitting regions, the at least one lens layer includes a plurality of lens units, and the plurality of lens units correspond to the sub-pixels one to one. Moreover, each of the plurality of lens units includes one or more lenses, the one or more lenses correspond to the light emitting regions one to one, and the one or more lenses is configured for causing the light rays emitted by the light emitting layer to deflect toward a direction close to a normal of the substrate. By regulating the quantity of the lens layer or regulating the quantity of the lenses, the equivalent focal length of the lens unit can be changed, so that the placement height of the lens unit matches with the focal length better, so that the lens units can converge the light rays better, thereby the display brightness of the display base board is increased. Moreover, the sub-pixel includes a plurality of light emitting regions, which can facilitate the detection and the repairing of the sub-pixel. If a certain light emitting region of the sub-pixel is abnormal, the other light emitting regions can display normally.

In order to make the above purposes, features and advantages of the present disclosure more apparent and understandable, the display base board, the display device and the manufacturing method of a display base board according to the present disclosure will be described in further detail below with reference to the drawings and the particular embodiments in the present disclosure.

Referring to FIG. 1, FIG. 1 is a display base board according to the present disclosure. The display base board includes a substrate 10, a light emitting layer 20, a packaging layer 30 and at least one lens layer 40.

Specifically, the substrate 10 may include a monocrystalline-silicon substrate or a polycrystalline-silicon substrate. The monocrystalline-silicon substrate refers to a substrate 10 manufactured by using a monocrystalline-silicon material. The polycrystalline-silicon substrate refers to a substrate 10 manufactured by using a polycrystalline-silicon material.

Moreover, the display base board may further include a driving circuit 80 disposed on the substrate 10. The driving circuit 80 is connected to the light emitting layer 20, and is configured for causing the light emitting layer 20 to emit light rays. In an alternative embodiment, the driving circuit 80 may be a complementary metal oxide semiconductor (CMOS) circuit, and therefore the driving circuit 80 may be formed by using a CMOS process. As an example, the driving circuit 80 may be formed by using a P-well CMOS process, an N-well CMOS process and a double-well CMOS process.

In the driving circuit 80, the driving circuit 80 may include a deep N-well layer formed on the substrate 10, a medium-voltage well layer disposed on the deep N-well layer, a lightly doped drain disposed on the medium-voltage well layer, and a gate, a source, a drain and so on disposed on the lightly doped drain. It should be noted that the driving circuit 80 formed by using the N-well CMOS process is an existing structure in the related art, and thus is not discussed further in the embodiments of the present application.

Further, referring to FIG. 1, the light emitting layer 20 is disposed at one side of the substrate 10. The light emitting layer 20, after connected to the driving circuit 80, under the driving by the driving circuit 80, may emit light rays. In addition, the light emitting layer 20 includes a plurality of sub-pixels 201, and the plurality of sub-pixels 201 may be distributed on the substrate 10 in an array. In the display base board, the display base board may further include a first electrode layer and a second electrode layer (not shown in the figure). The first electrode layer is disposed between the substrate 10 and the light emitting layer 20, and the second electrode layer is disposed at the side of the light emitting layer 20 away from the first electrode layer 60. The first electrode layer and the second electrode layer are connected to the driving circuit 80, thereby the connection of the driving circuit 80 and the light emitting layer 20 is realized.

Further, the packaging layer 30 is disposed at the side of the light emitting layer 20 away from the substrate 10. The packaging layer 30 may include an inorganic material, for example, SiNₓ and SiO₂. The refractive index of the packaging layer 30 is greater than or equal to 1.8, so as to diverge the light rays emitted by the light emitting layer 20 better.

Further, referring to FIG. 1, the lens layer 40 is disposed on the surface of the side of the packaging layer 30 away from the light emitting layer 20. The lens layer 40 includes a plurality of lens units 401, and the plurality of lens units 401 correspond to the sub-pixels 201 one to one; in other words, the orthographic projection on the substrate 10 of each of the plurality of lens units 401 and the orthographic projection on the substrate 10 of each of the sub-pixels 201 overlap. Accordingly, the light rays emitted by each of the sub-pixels 201 are refracted by the corresponding lens unit 401 and subsequently exits the display base board.

Moreover, in the present disclosure, the placement height of the lens layer 40 (which refers to the distance between the side of the light emitting layer 20 facing the packaging layer 30 and the side of the lens layer 40 facing the packaging layer 30) is reduced, so that most of the light rays emitted by the light emitting layer 20 can be collected into the lens units 401 to be refracted. However, after the placement height of the lens unit 401 is reduced, it easily happens that the focal length of the lenses 4011 included by the lens units 401 does not match with the placement height.

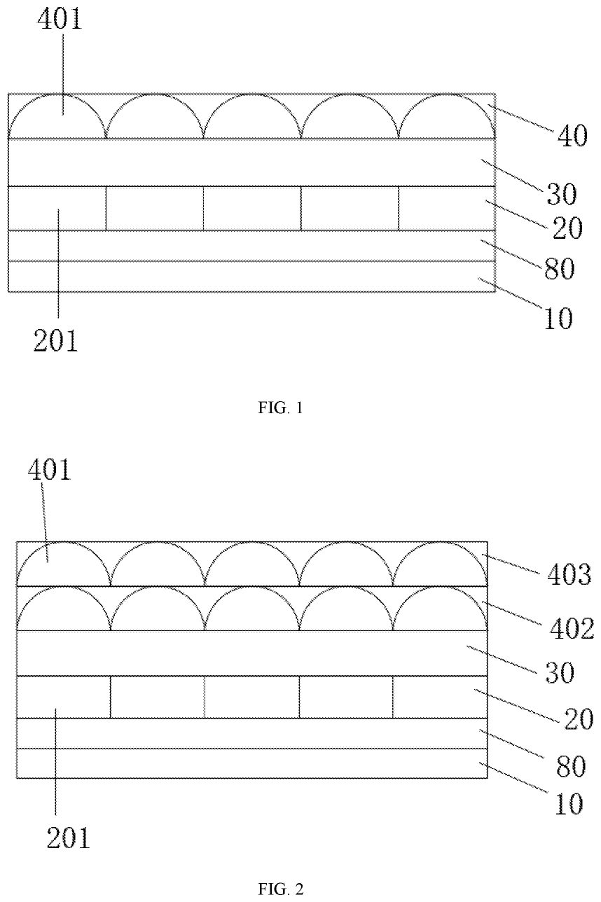

Therefore, in the present disclosure, referring to FIG. 2, the lens layer 40 is at least one layer; in other words, the lens layer 40 may be a single layer, double layers or more layers. When two or more lens layers 40 are overlaid in the light propagation direction, because each of the lens layers 40 has a certain deflection effect on the light, the equivalent focal length of the lens unit 401 in the lens layers 40 (i.e., the actual focal length of the lens units 401 obtained by the overlaying of the two or more lens layers 40) is reduced, so that the placement height of the lens unit 401 can be adapted for the equivalent focal length of the lens unit 401, therefore the effect of the convergence by the lens units 401 is improved.

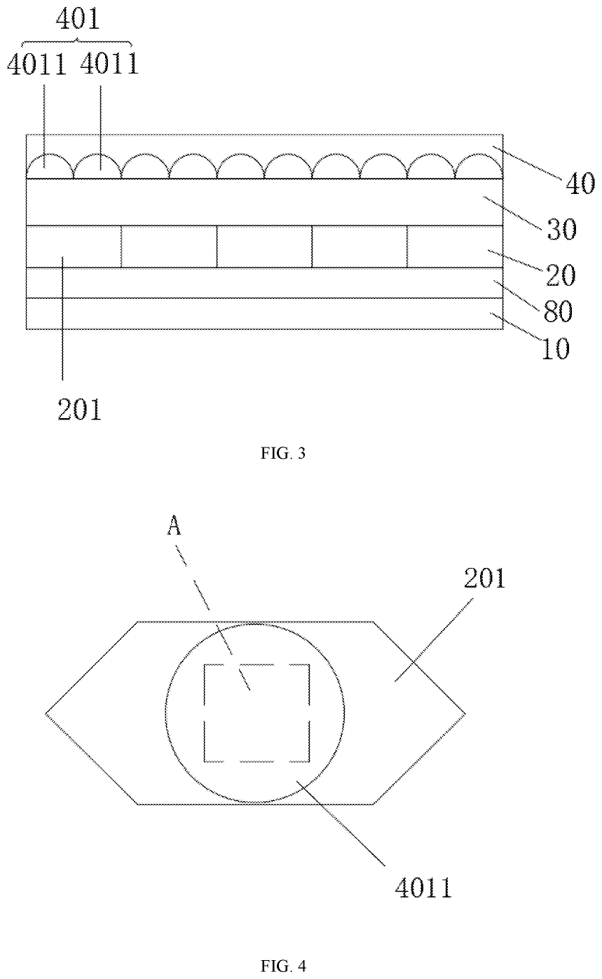

Optionally, referring to FIG. 3, each of the lens units 401 may include one or more lenses 4011, and the lenses 4011 are configured for causing the light rays emitted by the light emitting layer 20 to deflect toward a direction close to a normal of the substrate 10. Specifically, each of the lens units 401 may include one, two, three or more lenses 4011. Moreover, because the sub-pixels 201 correspond to the lens units 401 one to one, and the size of the sub-pixels 201 is generally constant, after the quantity of the lenses 4011 included by the lens units 401 is increased, the apertures of the lenses 4011 are required to be reduced correspondingly, which results in that the focal lengths of the lenses 4011 are reduced, thereby the equivalent focal lengths of the lens units 401 are reduced. Accordingly, the equivalent focal lengths of the lens units 401 can match with the placement heights of the lens units 401, thereby the effect of the convergence of the lens units 401 is improved, so as to increase the normal-angel brightness of the display base board (wherein the normal-angel brightness refers to the brightness in the direction of the normal of the substrate 10).

When a plurality of lens layers 40 or a lens unit 401 including a plurality of lenses 4011 are used, the equivalent focal length of each of the lens units 401 may be changed, so that the placement height of the lens layer 40 can match with the equivalent focal length of the lens unit 401 better, thus the lens layer 40 can converge the light rays better.

Optionally, in order to further increase the display brightness of the display base board, in the present disclosure, the refractive index of the lens layer 40 and the refractive index of the packaging layer 30 may be equal; in other words, the refractive index of the lens layer 40 is greater than or equal to 1.8. As an example, the refractive index of the lens layer 40 may be 1.8, 1.85, 1.9, 1.95, 2.0 and so on. By causing the refractive index of the lens layer 40 and the refractive index of the packaging layer 30 to match, the lens layer 40 can converge the light rays refracted by the packaging layer 30 better, so that the lens layer 40 can take out the light energy in the waveguide mode in the packaging layer 30, thereby the display brightness of the display base board is increased. The material of the lens layer 40 may include SiNₓ, SiC, SiO₂ and so on.

It should be noted that, herein, the refractive index of the lens layer 40 and the refractive index of the packaging layer 30 may not be totally equal. It is merely required that the difference between the refractive index of the lens layer 40 and the refractive index of the packaging layer 30 is in a certain range (for example, between 0-1), and the lens layer 40 can converge the light rays refracted by the packaging layer 30 better, and take out the light energy in the waveguide mode in the packaging layer 30.

In the display base board according to the present disclosure, by regulating the quantity of the lens layer 40 or regulating the quantity of the lenses 4011, the equivalent focal length of the lens layer 40 can be changed, so that the placement height of the lens layer 40 matches with the focal length better, so that the lens layer 40 can converge the light rays better, thereby the display brightness of the display base board is increased. Moreover, the refractive index of the lens layer 40 and the refractive index of the packaging layer 30 match, so that the lens layer 40 can take out the light energy in the waveguide mode in the packaging layer 30.

In an alternative embodiment, the present disclosure further provides a display base board. In the display base board, a ratio of a distance between a side of the light emitting layer 20 facing the packaging layer 30 and the side of the lens layer 40 facing the packaging layer 30 to an equivalent focal length of the lens unit 401 is greater than or equal to 0.5, and less than or equal to 1.

Specifically, for the display base boards of unequal aperture ratios, merely if the placement height of the lens layer 40 (which refers to the distance between the surface of the side of the light emitting layer 20 facing the packaging layer 30 and the surface of the side of the lens layer 40 facing the packaging layer 30) is equal to the focal length of the lenses, the lenses can have the optimum effect of convergence. In addition, with the increasing aperture ratio, the condition of the adaptation between the focal length and the placement height becomes less strict. However, it is always required that the placement height is close to the focal length, to have the optimum effect of convergence.

However, in the present disclosure, because each of the lens units 401 includes one or more lenses 4011, it is required that the equivalent focal length of the lens unit 401 and the placement height of the lens units 401 are equal, so that the lens units 401 can have the optimum effect of convergence. As an example, when the aperture ratio of the light emitting layer 20 of the display base board is 60%, the ratio of the placement height of the lens unit 401 (the distance between the side of the light emitting layer 20 facing the packaging layer 30 and the side of the lens layer 40 facing the packaging layer 30) to the equivalent focal length of the lens unit 401 is greater than or equal to 0.5, and less than or equal to 1. In that range, the lens units 401 have the optimum effect of the convergence of the light rays, so that the normal-angel brightness of the display base board can be increased more effectively.

Further, in the present disclosure, the placement height of the lens unit 401 in the lens layer 40 (which refers to the distance between the side of the light emitting layer 20 facing the packaging layer 30 and the side of the lens layer 40 facing the packaging layer 30) should be as low as possible. In practical applications, the placement height of the lens unit 401 (the distance between the side of the light emitting layer 20 facing the packaging layer 30 and the side of the lens layer 40 facing the packaging layer 30) is greater than or equal to 0.8 μm, and less than or equal to 1.2 μm. As an example, the placement height of the lens unit 401 may be 0.8 μm, 0.9 μm, 1.0 μm, 1.1 μm, 1.2 μm and so on.

In the display base board according to the present disclosure, as the placement height of the lens unit 401 is reduced, the distance from the lens units 401 to the light emitting layer 20 is low, so that more light rays emitted by the light emitting layer 20 can enter the lens units 401 more, and be refracted and converged by the lens units 401 to the normal angle, thereby the normal-angel brightness of the display base board is increased.

In an alternative embodiment, a display base board is further provided by the present disclosure. Referring to FIG. 2, in the display base board, the at least one lens layer 40 includes a first lens layer 402 and a second lens layer 403, wherein the material of the first lens layer 402 and the material of the second lens layer 403 are the same or different.

Specifically, the lens units 401 included by the first lens layer 402 and the lens units 401 included by the second lens layer 403 correspond one to one. It can be understood that the first lens layer 402 and the second lens layer 403 totally overlap. The first lens layer 402 and the second lens layer 403 may employ the same material. For example, both of the first lens layer 402 and the second lens layer 403 are manufactured by using SiNₓ. Different materials may also be selected as the materials of the first lens layer 402 and the second lens layer 403. For example, the first lens layer 402 may be manufactured by using SiNₓ, and the second lens layer 403 may be manufactured by using SiC. However, preferably, the refractive index of the first lens layer 402 and the refractive index of the second lens layer 403 are equal, so that more light rays can be refracted by the first lens layer 402 and the second lens layer 403.

After the first lens layer 402 and the second lens layer 403 are overlaid, the equivalent focal length of the lens unit 401 can be reduced, so that the placement height of the lens unit 401 can match with the equivalent focal length of the lens unit 401 better, so that the lens units 401 can converge the light rays emitted by the light emitting layer 20 better.

In an alternative embodiment, a display base board is further provided by the present disclosure. Referring to FIGS. 4, 5 and 6, in the display base board, at least one of the sub-pixels 201 includes a plurality of light emitting regions A, wherein the lenses 4011 correspond to the light emitting regions A one to one.

Specifically, when each of the lens units 401 includes a plurality of lenses 4011, correspondingly, each of the sub-pixels 201 is also required to include a plurality of light emitting regions A, and each of the lenses is correspondingly placed into each of the light emitting regions A included by the sub-pixel 201, so that the light rays emitted by each of the light emitting regions A can totally enter the corresponding lens 4011, so that the lens units 401 can converge the light rays.

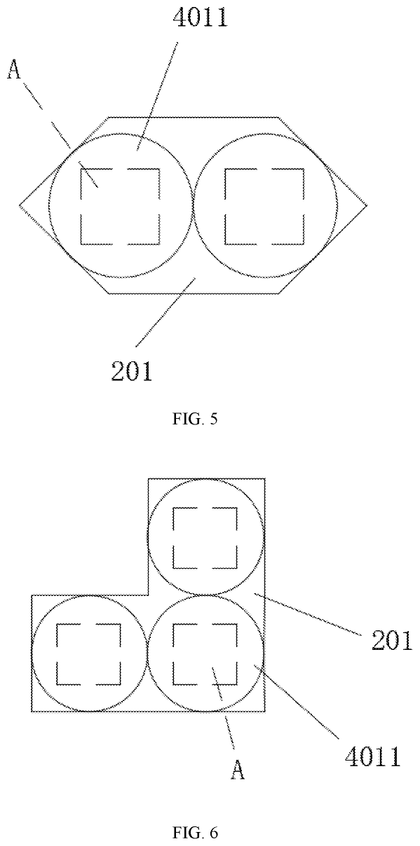

As an example, referring to FIG. 4, in the present embodiment, the lens unit 401 includes merely one lens 4011, and therefore the sub-pixel 201 includes merely one light emitting region A. Referring to FIG. 5, in the present embodiment, the lens unit 401 includes two lenses 4011, so that the sub-pixel 201 includes two light emitting regions A, and each of the lenses 4011 is located at the position where the corresponding light emitting region A is located. Referring to FIG. 6, in the present embodiment, the lens unit 401 includes three lenses 4011, so that the sub-pixel 201 includes three light emitting regions A, each of the lenses 4011 is located at the position where the corresponding light emitting region A is located, and the shape of the sub-pixel 201 is different from the shapes of the sub-pixels 201 according to the two preceding embodiments.

In the display base board according to the present disclosure, the sub-pixel 201 includes a plurality of light emitting regions A, which can facilitate the detection and the repairing of the sub-pixel 201, wherein if a certain light emitting region A of the sub-pixel 201 is abnormal, the other light emitting regions A can display normally. Furthermore, the light emitting regions A of the sub-pixel 201 correspond to the lenses 4011 one to one, so that if a certain light emitting region A of the sub-pixel 201 is abnormal, the effect of light focusing of the other light emitting regions A is not affected. If all of the light emitting regions A of one sub-pixel 201 uses one lens 4011 for light focusing, once a certain light emitting region A is abnormal, the overall effect of light focusing of the sub-pixel is affected.

Optionally, as each of the sub-pixels 201 includes a plurality of light emitting regions A, referring to FIG. 7, the display base plate includes a pixel definition layer 50, the pixel definition layer 50 is disposed between the substrate 10 and the light emitting layer 20, and the pixel definition layer 50 is configured for segmenting the sub-pixels 201 into the plurality of light emitting regions A. Moreover, the display base plate further includes the first electrode layer 60 disposed between the pixel definition layer 50 and the substrate 10, and the first electrode layer 60 may supply electric energy to the light emitting layer 20.

After the pixel definition layer 50 segments the sub-pixels 201 into the plurality of light emitting regions A, merely the light emitting regions A not covered by the pixel definition layer 50 can contact the first electrode layer 60, thereby the light-emission is realized, and the sub-pixels 201 covered by the pixel definition layer 50 cannot contact the first electrode layer 60, and thus cannot emit light.

Optionally, the first electrode layer 60 includes a plurality of first electrodes, and the plurality of light emitting regions A located within the same sub-pixel 201 are connected to the same first electrode. In addition, an insulating layer is further disposed between the first electrode layer 60 and the substrate 10, and the first electrode layer 60 is connected to the driving circuit 80 on the substrate 10 through a via hole (for example, a metal via hole) penetrating the insulating layer. Accordingly, the driving circuit 80 can supply electric energy to the first electrode layer 60. Furthermore, because the plurality of light emitting regions A of the same sub-pixel 201 are connected to the same first electrode, simultaneous light emission of the plurality of light emitting regions A in one sub-pixel 201 is realized.

In the display base board according to the present disclosure, by using the lens units 401 including a plurality of lenses 4011, matching between the equivalent focal length and the placement height of the lens unit 401 is realized. Moreover, by configuring that one sub-pixel 201 includes a plurality of light emitting regions A, and each of the lenses 4011 corresponds to each of the light emitting regions A, more light rays emitted by the sub-pixel 201 of the light emitting layer 20 can enter the lens units 401 more, and be refracted by the lens units 401, so as to increase the normal-angel brightness of the display base board.

In an alternative embodiment, the present disclosure further provides a display base board. In the display base board, the sub-pixels 201 include a first sub-pixel, a second sub-pixel and a third sub-pixel. The quantities of the lenses 4011 included by the lens units 401 that at least two of the first sub-pixel, the second sub-pixel and the third sub-pixel correspond to are unequal to each other.

Specifically, in the present embodiment, the display brightnesses of the different sub-pixels 201 may be changed by changing the quantities of the lenses included by the lens units 401 corresponding to the different sub-pixels 201.

For example, the first sub-pixel, the second sub-pixel and the third sub-pixel are a red sub-pixel 201, a blue sub-pixel and a green sub-pixel respectively. By increasing the quantity of the lenses 4011 of the lens unit 401 corresponding to the green sub-pixel, the normal-angle display brightness to the green light rays of the display base board can be increased. Because the human eyes have a higher sensitivity to the green light, although the density of the sub-pixels 201 is not increased directly, the visual-effect pixel density of the human eyes can be increased effectively, so that the display brightness of the display base board that is observed by the human eyes is higher.

By changing the quantities of the lenses included by the lens units 401 corresponding to the different sub-pixels 201, independent configuration of the different sub-pixels 201 is realized, so that the display base board can be designed better according to demands.

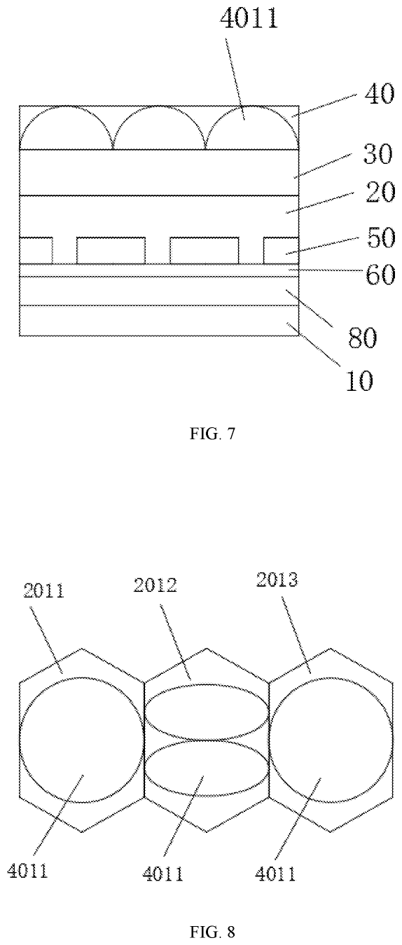

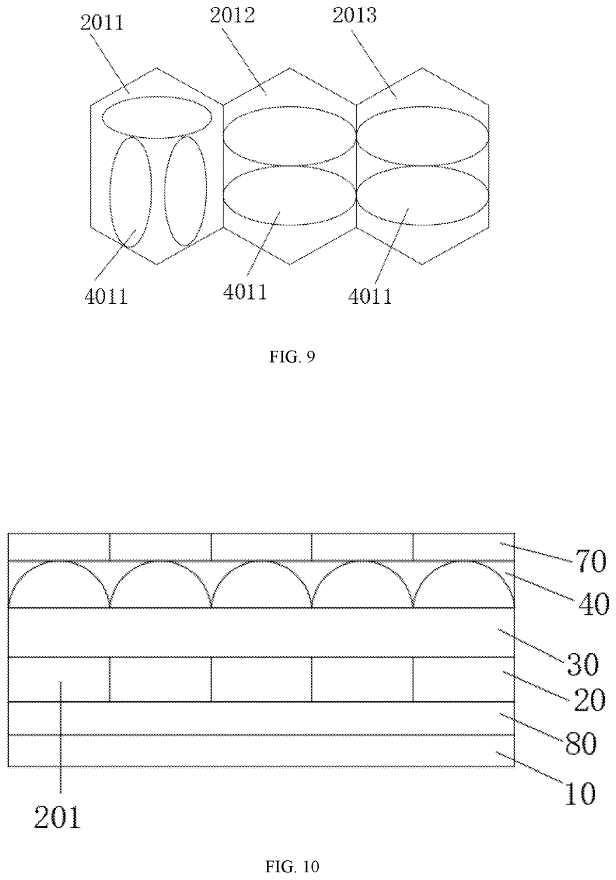

In an alternative embodiment, a display base board is further provided by the present disclosure. Referring to FIGS. 8 and 9, in the display base board, the plurality of sub-pixels 201 include a red sub-pixel 2011, a green sub-pixel 2012 and a blue sub-pixel 2013. The quantity of the lenses 4011 included by the lens unit 401 corresponding to the green sub-pixel 2012 is greater than the quantity of the lenses 4011 included by the lens unit 401 corresponding to the red sub-pixel 2011 and the quantity of the lenses 4011 included by the lens unit 401 corresponding to the blue sub-pixel 2013. Alternatively, the quantity of the lenses 4011 included by the lens unit 401 corresponding to the red sub-pixel 2011 is greater than the quantity of the lenses 4011 included by the lens unit 401 corresponding to the green sub-pixel 2012 and the quantity of the lenses 4011 included by the lens unit 401 corresponding to the blue sub-pixel 2013.

Specifically, when the quantity of the lenses 4011 included by the lens unit 401 corresponding to the green sub-pixel 2012 is greater than the quantity of the lenses 4011 included by the lens unit 401 corresponding to the red sub-pixel 2011 and the quantity of the lenses 4011 included by the lens unit 401 corresponding to the blue sub-pixel 201, the normal-angel brightness of the green light rays emitted by the display base board is higher, and, as stated above, the brightness of the display base board that is observed by the human eyes is higher.

As an example, referring to FIG. 8, the ratio of the quantities of the lenses 4011 included by the lens units 401 corresponding to the red sub-pixel 2011, the green sub-pixel 2012 and the blue sub-pixel 2013 may be 1:2:1. In other words, the quantities of the lenses 4011 included by the lens units 401 corresponding to the red sub-pixel 2011 and the blue sub-pixel 2013 are one, and the quantity of the lenses 4011 included by the lens unit 401 corresponding to the green sub-pixel 2012 is two.

Further, in practical applications, the display base board easily has more red color at large angles. When the quantity of the lenses 4011 included by the lens unit 401 corresponding to the red sub-pixel 2011 is greater than the quantity of the lenses 4011 included by the lens unit 401 corresponding to the green sub-pixel 2012 and the quantity of the lenses 4011 included by the lens unit 401 corresponding to the blue sub-pixel 2013, the red light emitted by the display base board can exit at the normal angle better than the green light and the blue light, thereby weakening of the large-angle red light of the display base board is realized, so as to effectively inhibit the problem of color cast.

As an example, referring to FIG. 9, the ratio of the quantities of the lenses 4011 included by the lens units 401 corresponding to the red sub-pixel 2011, the green sub-pixel 2012 and the blue sub-pixel 2013 may be 3:2:2. In other words, the quantity of the lenses 4011 included by the lens unit 401 corresponding to the red sub-pixel 2011 is three, and the quantities of the lenses 4011 included by the lens units 401 corresponding to the blue sub-pixel 2013 and the green sub-pixel 2012 are two.

In the display base board according to the present disclosure, by independently configuring the quantities of the lenses 4011 included by the lens units 401 corresponding to the red sub-pixel 2011, the green sub-pixel 2012 and the blue sub-pixel 2013, the normal-angel brightnesses of the sub-pixels 201 of single colors of the display base board can be changed, thereby the display base board is designed according to different demands, the applicability of the display base board is improved.

Optionally, in an alternative embodiment, referring to FIG. 10, the display base board may further include an optical-filter layer 70, the optical-filter layer 70 is disposed at the side of the lens layer 40 away from the packaging layer 30, and optical filters of the optical-filter layer 70 correspond to the sub-pixels 201 one to one. The optical-filter layer 70 includes a red optical filter, a green optical filter and a blue optical filter.

The colors of the light rays emitted by the different sub-pixels 201 can be changed by using the optical filters of the different colors, thereby the color display of the display base board is realized.

On the basis of the same inventive concept, a display device is further provided in the present disclosure, wherein the display device includes any one of the display base boards described above in the present disclosure.

Specifically, the display device may be an OLED display screen, a mobile device such as a mobile phone, a wearable device such as a watch, a VR/AR device and so on, which may be selected correspondingly by a person skilled in the art according to the specific use of the display device, and is not discussed further herein.

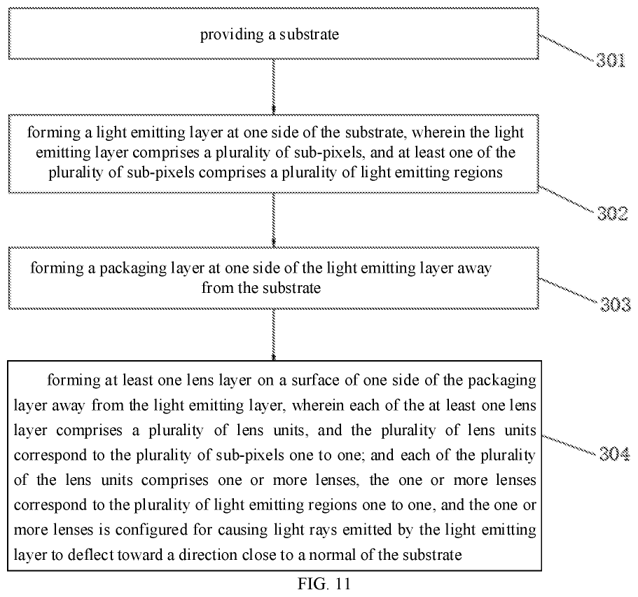

FIG. 11 shows a flow chart of the steps of a manufacturing method of a display base board according to the present disclosure. Referring to FIG. 11, the present disclosure provides a manufacturing method of a display base board, wherein the manufacturing method includes:

Step 301: providing a substrate 10.

Specifically, the substrate 10 may be a monocrystalline-silicon substrate 10 or a polycrystalline-silicon substrate 10. The step of completing the manufacturing of the substrate 10 may further include completing the manufacturing of the driving circuit 80 on the substrate 10.

Step 302: forming a light emitting layer 20 at one side of the substrate 10, wherein the light emitting layer 20 includes a plurality of sub-pixels 201, and at least one of the plurality of sub-pixels 201 includes a plurality of light emitting regions A.

Specifically, as each of the plurality of sub-pixels 201 includes a plurality of light emitting regions A, the step of completing the manufacturing of the light emitting layer 20 may further include completing the manufacturing of the first electrode layer 60, the second electrode layer and the pixel definition layer 50.

Step 303: forming a packaging layer 30 at the side of the light emitting layer 20 away from the substrate 10.

Specifically, an inorganic material is selected as the material of the packaging layer 30, for example, SiNₓ. The refractive index of the packaging layer 30 is greater than or equal to 1.8.

Step 304: forming at least one lens layer 40 on the surface of the side of the packaging layer 30 away from the light emitting layer 20, wherein each of the at least one lens layer 40 includes a plurality of lens units 401, and the plurality of lens units 401 correspond to the plurality of sub-pixels 201 one to one.

Each of the plurality of lens units 401 includes one or more lenses 4011, the one or more lenses 4011 correspond to the plurality of light emitting regions A one to one, and the one or more lenses 4011 are configured for causing the light rays emitted by the light emitting layer 20 to deflect toward a direction close to a normal of the substrate 10.

Specifically, the material of the lens layer 40 may be selected from SiNₓ, SiC, SiO₂ and so on. The refractive index of the lens layer 40 is greater than or equal to 1.8. In addition, the equivalent focal length of the lens unit 401 and the placement height of the lens unit 401 are required to match, so that the lens units 401 can converge the light rays better.

In the display base board manufactured by using the manufacturing method of a display base board according to the present disclosure, by regulating the quantity of the lens layer 40 or regulating the quantity of the lenses 4011, the equivalent focal length of the lens unit 401 can be changed, so that the placement height of the lens unit 401 matches with the focal length better, so that the lens units 401 can converge the light rays better, thereby the display brightness of the display base board is increased. Moreover, the sub-pixel includes a plurality of light emitting regions, which can facilitate the detection and the repairing of the sub-pixel, wherein if a certain light emitting region of the sub-pixel is abnormal, the other light emitting regions can display normally.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “include” does not exclude elements or steps that are not listed in the claims. The word “a” or “an” preceding an element does not exclude the existing of a plurality of such elements. The present disclosure may be implemented by means of hardware including several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A display base board, wherein the display base board comprises:
a substrate;
a light emitting layer disposed at one side of the substrate, wherein the light emitting layer comprises a plurality of sub-pixels, and at least one of the plurality of sub-pixels comprises a plurality of light emitting regions;
a packaging layer disposed at one side of the light emitting layer away from the substrate; and
at least one lens layer provided on a surface of one side of the packaging layer away from the light emitting layer, wherein each of the at least one lens layer comprises a plurality of lens units, and the plurality of lens units correspond to the plurality of sub-pixels one to one; and
each of the plurality of lens units comprises one or more lenses, the one or more lenses correspond to the plurality of light emitting regions one to one, and the one or more lenses are configured for causing light rays emitted by the light emitting layer to deflect toward a direction close to a normal of the substrate.

2. The display base board according to claim 1, wherein a ratio of a distance between a surface of one side of the light emitting layer facing the packaging layer and a surface of one side of each of the at least one lens layer facing the packaging layer to an equivalent focal length of the lens unit is greater than or equal to 0.5, and less than or equal to 1.

3. The display base board according to claim 2, wherein the distance between the surface of the side of the light emitting layer facing the packaging layer and the surface of the side of each of the at least one lens layer facing the packaging layer is greater than or equal to 0.8 μm, and less than or equal to 1.2 μm.

4. The display base board according to claim 1, wherein a refractive index of each of the at least one lens layer is greater than or equal to 1.8.

5. The display base board according to claim 1, wherein a refractive index of the packaging layer and a refractive index of each of the at least one lens layer are equal.

6. The display base board according to claim 1, wherein the at least one lens layer includes a first lens layer and a second lens layer; and
a material of the first lens layer and a material of the second lens layer are the same or different.

7. The display base board according to claim 6, wherein the display base plate further comprises:
a pixel definition layer disposed between the substrate and the light emitting layer, wherein the pixel definition layer segments each of the plurality of sub-pixels into the plurality of light emitting regions.

8. The display base board according to claim 7, wherein the display base plate further comprises:
a first electrode layer disposed between the pixel definition layer and the substrate, wherein the first electrode layer comprises a plurality of first electrodes, and the plurality of light emitting regions located in a same sub-pixel are connected to a same first electrode.

9. The display base board according to claim 1, wherein the plurality of sub-pixels comprises a first sub-pixel, a second sub-pixel and a third sub-pixel; and
quantities of the lenses comprised by the lens units that at least two of the first sub-pixel, the second sub-pixel and the third sub-pixel correspond to are unequal to each other.

10. The display base board according to claim 1, wherein the plurality of sub-pixels comprise a red sub-pixel, a green sub-pixel and a blue sub-pixel; and
a quantity of the lenses comprised by the lens unit corresponding to the green sub-pixel is greater than a quantity of the lenses comprised by the lens unit corresponding to the red sub-pixel and a quantity of the lenses comprised by the lens unit corresponding to the blue sub-pixel; or
the quantity of the lenses comprised by the lens unit corresponding to the red sub-pixel is greater than the quantity of the lenses comprised by the lens unit corresponding to the green sub-pixel and the quantity of the lenses comprised by the lens unit corresponding to the blue sub-pixel.

11. The display base board according to claim 1, wherein the plurality of sub-pixels comprise a red sub-pixel, a green sub-pixel and a blue sub-pixel, and a ratio of quantities of the lenses comprised by the lens units corresponding to the red sub-pixel, the green sub-pixel and the blue sub-pixel is 1:2:1.

12. The display base board according to claim 1, wherein the plurality of sub-pixels comprise a red sub-pixel, a green sub-pixel and a blue sub-pixel, and a ratio of quantities of the lenses comprised by the lens units corresponding to the red sub-pixel, the green sub-pixel and the blue sub-pixel is 3:2:2.

13. The display base board according to claim 1, wherein the display base plate further comprises:
an optical-filter layer disposed at one side of the at least one lens layer away from the packaging layer, wherein optical filters of the optical-filter layer correspond to the sub-pixels one to one;
wherein the optical-filter layer comprises a red optical filter, a green optical filter and a blue optical filter.

14. A display device, wherein the display device comprises the display base board according to claim 1.

15. A manufacturing method of a display base board, wherein the manufacturing method comprises:
providing a substrate;
forming a light emitting layer at one side of the substrate, wherein the light emitting layer comprises a plurality of sub-pixels, and at least one of the plurality of sub-pixels comprises a plurality of light emitting regions;
forming a packaging layer at one side of the light emitting layer away from the substrate; and
forming at least one lens layer on a surface of one side of the packaging layer away from the light emitting layer, wherein each of the at least one lens layer comprises a plurality of lens units, and the plurality of lens units correspond to the plurality of sub-pixels one to one; and
each of the plurality of the lens units comprises one or more lenses, the one or more lenses correspond to the plurality of light emitting regions one to one, and the one or more lenses are configured for causing light rays emitted by the light emitting layer to deflect toward a direction close to a normal of the substrate.

16. The display base board according to claim 2, wherein the at least one lens layer includes a first lens layer and a second lens layer; and
a material of the first lens layer and a material of the second lens layer are the same or different.

17. The display base board according to claim 3, wherein the at least one lens layer includes a first lens layer and a second lens layer; and
a material of the first lens layer and a material of the second lens layer are the same or different.

18. The display base board according to claim 2, wherein the plurality of sub-pixels comprise a red sub-pixel, a green sub-pixel and a blue sub-pixel, and a ratio of quantities of the lenses comprised by the lens units corresponding to the red sub-pixel, the green sub-pixel and the blue sub-pixel is 1:2:1.

19. The display base board according to claim 2, wherein the plurality of sub-pixels comprise a red sub-pixel, a green sub-pixel and a blue sub-pixel, and a ratio of quantities of the lenses comprised by the lens units corresponding to the red sub-pixel, the green sub-pixel and the blue sub-pixel is 3:2:2.

20. The display base board according to claim 2, wherein the display base plate further comprises:
an optical-filter layer disposed at one side of the at least one lens layer away from the packaging layer, wherein optical filters of the optical-filter layer correspond to the sub-pixels one to one;
wherein the optical-filter layer comprises a red optical filter, a green optical filter and a blue optical filter.
